(19) United States
(12) Patent Application Publication
(10) Pub. No.: US 2010/0221463 A1
(43) Pub. Date: Sep. 2, 2010

(54) Integrated Encapsulation for MEMS Devices

(75) Inventors: Imed Zine-El-Abidine, Kingston (CA); Michael Okoniewski, Calgary (CA)

Correspondence Address: FULBRIGHT & JAWORSKI L.L.P., 600 CONGRESS AVE., SUITE 2400, AUSTIN, TX, 78701, US

(73) Assignee: UTI LIMITED PARTNERSHIP, Calgary (CA)

(21) Appl. No.: 12/607,415

(22) Filed: Oct. 28, 2009

Related U.S. Application Data
(60) Provisional application No. 61/109,420, filed on Oct. 29, 2008.

(51) Int. Cl. G03F 7/20; B32B 1/00

(52) U.S. Cl. 428/34.1; 430/322; 430/325; 430/312; 430/319

(57) ABSTRACT

In one general aspect, methods and articles of manufacture for creating micro-structures are disclosed. In one embodiment, the micro-structures are configured to provide a desired level of hermiticity to other micro-sized devices, such as MEMS and microfluidic devices. In one embodiment, the microstructures are formed from a single species of photoresist, where the photoresist is lithographically patterned to encapsulate the micro-sized device. In general, the ability to form an encapsulating micro-structure from a single photoresist relies in part on applying variable light doses to a later of photoresist to affect a desired level of cross-linking within the photoresist.

### CROSS-REFERENCE TO RELATED APPLICATIONS

This application claims the benefit of U.S. Provisional Application No. 61/109,420 filed Oct. 29, 2008, the entire contents of which is specifically incorporated herein by reference without disclaimer.

### TECHNICAL FIELD

This disclosure relates to methods for fabricating micro-sized structures, and more particularly to micro-sized structures made from photoresist for encapsulating other micro-sized elements.

### BACKGROUND OF THE INVENTION

Microelectromechanical systems (MEMS) are devices that typically range in size from about twenty microns to about one millimeter, and can include components that range from about 1 to 100 microns. In some cases, MEMS devices are fully self-contained and self-supportive, including all necessary hardware to perform its designed function without external interaction. For example, a MEMS device can include computer circuitry, including processors and sensors that can interact with its surroundings, and telemetry components to relay information to a remote receiver.

MEMS can be advantageous for a variety of applications, generally including electronics, printing, gyroscopes, displays, and pressure sensors, for example. Bio-MEMS refers to a class of MEMS with biological applications, including so-called “labs on chips,” which are miniaturized devices that can analyze compounds and biological material at low cost and with high throughput. Other bio-MEMS applications include diagnostics, drug delivery systems, surgical instrumentation, and implantable, artificial organs.

### SUMMARY OF THE INVENTION

In general, according to one aspect, methods for creating micro-structures are provided. The micro-structures can be formed by photo-induced molecular cross-linking of a single type of photoresist. In general, the components of the micro-structure (e.g., the support structures) can be created by exposing portions of a photoresist to a variable dose of radiation that results in either complete or partial cross-linking, the choice of which can depend on the purpose of the component. Structural elements can be added in a piece-wise fashion by fully cross-linking some portions of a photoresist layer, while only partially cross-linking others. The partially cross-linked portions of the photoresist can be removed by washing in a suitable solvent, leaving behind a desired structural component. In some embodiments, the partially cross-linked structural elements can include holes or cavities that allow a solution to penetrate through a partially-crosslinked layer and dissolve underlying, un-exposed, i.e., non-crosslinked, photoresist. A micro-structure results, that includes a chamber or space which can be used to encapsulate a micro-device, such as a MEMS or bio-MEMS device.

In a first aspect, a method for fabricating a micro-structure includes hardening one or more areas of a photoresist layer to provide one or more support structures. The method further includes at least partially hardening a selected thickness of the photoresist layer in proximity to the one or more support structures to produce at least one structural member that couples with at least one of the support structures. The method further includes dissolving non-hardened photoresist to produce the micro-structure.

Implementations can include any, all, or none of the following features. The hardening can include exposing the photoresist to electromagnetic radiation having an energy substantially corresponding to the energy necessary to initiate a molecular cross-linking reaction within the photoresist. The photoresist can be a polymer. The photoresist can be a photoresist from the SU-8 2000 family of photoresists. The photoresist can be SU-8 2075. The support structure can be a post, wall, or multi-wall micro-sized support structure. The at least partially hardening a selected thickness of the photoresist layer in proximity to the one or more support structures to produce at least one structural member can include exposing the photoresist layer to a radiation dose greater than a dose required to initiate cross-linking of the photoresist, but less than the dose required to fully cross-link a total thickness of the photoresist. The dissolving non-hardened photoresist can include exposing the micro-structural element to photoresist developer. The structural member can include one or more holes or slots configured to allow a solution to penetrate the selected thickness of the photoresist layer. The holes or slots can be sized to preferentially allow the solution to penetrate the selected thickness, while restricting non-hardened photoresist from penetrating the selected thickness. The micro-structure can be formed around a micro-device. The micro-device can be a microelectromechanical system or a microfluidic system. The micro-structure can be configured to provide a variable level of hermiticity to the micro-device. The micro-structure can be configured to allow a component of the micro-device to extend through the micro-structure, such that a desired level of hermiticity can be provided to the micro-device while allowing the micro-device to be interfaced with other devices exterior to the micro-structure. The micro-structure can be formed from one species of photoresist.

In a second aspect, a method for packaging a MEMS device includes forming a hardened border section of a photoresist layer in proximity to a MEMS device by exposing the border section to a dose of radiation to crosslink the photoresist in the border section using a first lithographic mask. The method further includes replacing the first lithographic mask with a second lithographic mask and exposing the photoresist layer with a dose of radiation to partially crosslink a superficial portion of the photoresist layer. The method further includes wherein the second lithographic mask is configured to produce a plurality of holes in the superficial portion of the photoresist layer. The method further includes dissolving remaining non-crosslinked photoresist using a developer solution, thereby creating a chamber that encloses the MEMS device. The method further includes optionally applying a top-layer of photoresist to seal the plurality of holes.

Implementations can include any, all, or none of the following features. The method can include applying a metal layer upon the top-layer of photoresist. The applying a metal layer can include one or more of physical vapor deposition, and chemical vapor deposition. The applying a metal layer can include sputtering one or more of titanium, chromium, gold, or aluminum.

In a third aspect, an article of manufacture includes one or more micro-structural supports formed from hardened photoresist and configured to support a micro-structural element composed of the photoresist that spans the one or more micro-structural supports. The device further includes wherein the article of manufacture configured to encapsulate a MEMS device, thereby providing a variable level of hermiticity.

In a fourth aspect, a method of forming a micro-structure for encapsulating a micro-device includes cross-linking, to variable extents, select thicknesses and areas of a photoresist layer using a lithographic mask, the lithographic mask being configured to produce patterns of variably-attenuated electromagnetic radiation. The method further includes wherein the patterns define various structural elements of the micro-structure by virtue of the cross-linked thicknesses and areas. The method further includes dissolving non-crosslinked photoresist, thereby forming a cavity suitable for encapsulating the micro-device.

Implementations can include any, all, or none of the following features. The micro-device can be a MEMS device.

The details of one or more embodiments of this disclosure are set forth in the accompanying drawings and the description below. Other features, objects, and advantages will be apparent from the description and drawings, and from the claims.

Unless otherwise defined, all technical and scientific terms used herein have the same meaning as commonly understood by one of ordinary skill in the art to which this disclosure belongs. Although methods and materials similar or equivalent to those described herein can be used in the practice or testing of the present disclosure, suitable methods and materials are described below. In addition, the materials, methods, and examples are illustrative only and not intended to be limiting. All publications, patent applications, patents, and other references mentioned herein are incorporated by reference in their entirety. In case of conflict, the present specification, including definitions, will control.

### BRIEF DESCRIPTION OF DRAWINGS

FIG. 1 is an illustration of a MEMS device that has been encapsulated by a micro-structure according to one embodiment.

FIG. 2 generally illustrates the relationship between exposure dose and photoresist thickness after development.

FIG. 3 illustrates steps for forming a micro-structure, according to one embodiment.

FIGS. 4A-4E show steps for forming a micro-structure, according to one embodiment.

FIG. 5 is a scanning electron microscope (SEM) image of a micro-structure, according to one embodiment.

FIG. 6 is a schematic of the image in FIG. 5.

FIG. 7 shows a plot of photoresist thickness versus radiation dose.

FIG. 8 shows steps for forming a micro-structure, according to one embodiment.

FIG. 9 illustrates a bake cycle, according to one embodiment.

FIG. 10 illustrates a model for determining liquid penetration through a lid of a micro-structure, according to one embodiment.

FIG. 11 shows simulations of the model shown in FIG. 10, when solvent is used as a liquid.

FIG. 12 shows simulations of the model shown in FIG. 10, when photoresist is used as the liquid.

FIG. 13 shows SEM images of two micro-structures, according to two embodiments.

FIG. 14 shows SEM images of (a) a surface of a micro-structure and (b) a magnified portion.

FIG. 15 shows SEM images of a micro-structure comprising a metal layer, according to one embodiment.

FIG. 16 shows SEM images of one embodiment of a micro-structure and the print of the micro-structure.

FIG. 17 shows SEM images of a hermetic micro-structure with (a) sputtered metal and (b) plated metal.

FIG. 18 illustrates one embodiment of a lithographic mask for creating a micro-structure.

Like reference symbols in the various drawings indicate like elements.

### DETAILED DESCRIPTION

In one general aspect, methods for fabricating micro-structures from a single photoresist are provided. In general, a micro-structure can be fabricated by a process that includes depositing a layer of a light-activated photoresist, exposing selected portions of the photoresist to light to effect a selected amount of hardening, and subsequently depositing and exposing additional photoresist to build upon the first, hardened, portion. In some embodiments, micro-structures formed by the methods provided herein can provide a selected level of hermiticity, or non-hermiticity, for other, micro-sized objects encapsulated within the micro-structure. In select embodiments, micro-sized objects include microelectromechanical (MEMS) systems and micro-fluidic parts.

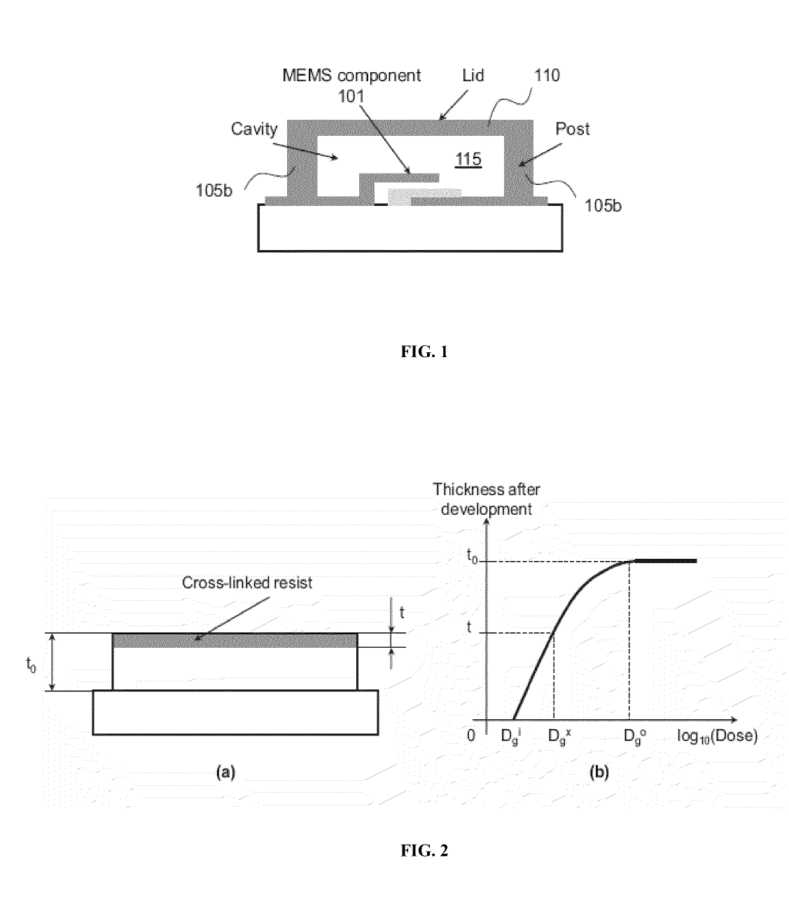

FIG. 1 is an illustration of a MEMS device 101 that has been encapsulated or packaged by a micro-structure formed from a single photoresist. The micro-structure includes posts 105a-b and a lid 110 and forms a cavity 115 around the MEMS device 101. In an alternative embodiment of FIG. 1, the posts 105a-b may be replaced with walls (not shown in FIG. 1) upon which a square lid may be integrated, thereby encapsulating the MEMS device 101 completely.

Generally, some lithographic resists are polymers that can be deposited onto a surface by spin-coating or other methods known to those skilled in the art. In some cases, polymeric negative photoresists can undergo molecular cross-linking upon exposure to certain colored light, which has the effect of hardening certain portions (e.g., all portions, or partial portions) of the photoresist where light was absorbed. Generally, lithographic masks can be used to create patterned areas that allow light to pass through to areas where hardening is desired; after exposure to light, the unexposed areas can be washed away using a developer solution.

In general, the photoresist can be selected based on the desired properties and function of the end micro-structure. In select embodiments, the photoresist is a negative photoresist. In certain embodiments, the photoresist is one of the family of SU-8 negative photoresists, including, for example, SU-8 2000, SU-8 2025, and SU-8 2100, sold by MicroChem company in Newton, Mass., USA.

In general, the developer can be any suitable solvent that substantially dissolves uncured (i.e., non-hardened) photoresist. In select embodiments, the developer can be chosen such that it preferentially dissolves photoresist (positive or negative) either after becoming cross-linked, or in its native, non-activated state.

In general, micro-structures of the type described herein can provide protection and packaging for MEMS and other devices. In general, because the micro-structures are formed from a single photoresist material that can be hardened using light, MEMS encapsulation may be realized without the use of high-temperature curing steps that could degrade or damage the MEMS device.

In general, the level to which some negative photoresists can become hardened can be in direct relation to the dose of light radiation the photoresist is exposed to. This principle can generally be exploited to build micro-structural elements of varying complexity, as described herein.

An interface gel dose Dⁱ_{g} can be the critical dose of light radiation to start a molecular cross-linking process of a negative photoresist. D⁰_{g} can be the dose required to fully cross-link the photoresist. In general, for a dose D^{x}_{g} larger than Dⁱ_{g} and less than D⁰_{g}, a portion of the photoresist monomers may become cross-linked, and therefore hardened. Referring to FIG. 2(a-b), and without wishing to be bound by theory, it can be possible to selectably cross-link (i.e., harden) a thickness t within the total thickness t₀ of a deposited layer of photoresist by controlling the light exposure dose of the unexposed photoresist. FIG. 2(b) generally shows the relationship between exposure dose and photoresist thickness after development. In general, the dose can be expressed by D=P×ΔT, where D is the dose in mJ/cm², P is the power density of a lamp in mW/cm² and −T is the exposure time in seconds.

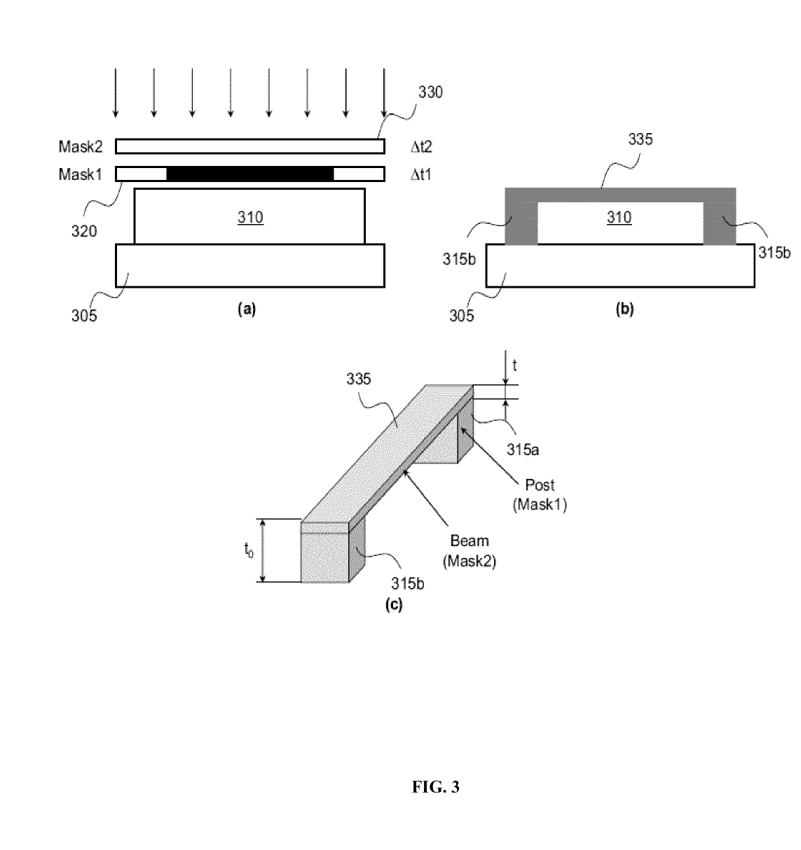

In general, the structure illustrated in FIG. 1 can be created using one photoresist material and exposing certain areas of the photoresist to a dose D of light for an appropriate time to piecewise build the structural members. A general process for forming the structure in FIG. 1 is exemplified in FIGS. 3a-c.

FIG. 3A illustrates a substrate 305 onto which a layer of negative photoresist 310 has been deposited. Generally, the photoresist layer 310 can be deposited by, for example, spin-coating, or spraying. A mask 320 can be placed over the photoresist layer 310 to prevent select portions of the photoresist layer 310 from receiving a dose of light radiation, while other portions can be exposed and hardened by the light-induced molecular cross-linking process. For example, posts 315a-b (similar to posts 105a-b in FIG. 1) can be created by exposing select portions of the photoresist layer 310 to a dose of radiation D equal to, but preferentially greater than, D⁰_{g}.

A second mask 330 can be used to pattern the “top” or “lid” 335 that spans the posts 315a-b, where the photoresist layer 310 is exposed to a dose D greater than Dⁱ_{g} and less than D⁰_{g}. This second exposure step can effect cross-linking in the superficial portion of the photoresist that will become the lid 335; i.e., cross-linking can preferentially occur only in thickness t as illustrated in FIG. 3C. This step and optional embodiments thereof are explained in greater detail below. After the second exposure step, developer can be added to the photoresist layer 310 which can substantially dissolve the non-crosslinked photoresist. The structure that remains after the developer wash is represented in FIG. 3C, which illustrates two posts 315a-b spanned by a beam (i.e., lid 335).

The creation of the posts 315a-b and beam 335 in FIG. 3 were described above using a sequential step method. In general, however, any method by which select portions of photoresist can be applied, preferentially hardened in select areas, and integrated into, or onto other photoresist portions can be used.

In one general embodiment, structures such as that illustrated in FIG. 3C can be created using a single-step approach. For example, one approach utilizes a patterned mask, where the mask has areas that block or attenuate radiation to various extents. FIG. 18 is an illustration of an exemplary mask 1800 that can be used in creating a micro-structure. The mask 1800 includes a light-restrictive region 1805 where a dose of light (e.g., the light flux) can be attenuated as it passes through the mask 1800 relative to non-light restrictive portions 1810a-b of the mask.

Exemplary mask 1800 includes two corners 1810a-b that are transparent to the wavelength (i.e., bandwidth) of light that can initiate cross-linking in the photoresist. As shown by the solid arrows 1815a-b, light can pass through the corners 1810a-b to fully cross-link the photoresist on the other side of the mask 1800, which can result in formation of posts, e.g., posts 315a-b in FIG. 3C. Another portion 1805 of the mask can attenuate the light to a selected degree (e.g., 20% attenuation, 40% attenuation, 60% attenuation, 80% attenuation), as illustrated by the dashed arrows 1810c emerging from the opposite side of the mask 1800 (i.e., opposite of the side where light impinges the mask 1800).

Reducing the light dose to which the photoresist is exposed can have the effect of controlling the thickness of the photoresist that becomes cross-linked. Thus, by judicious control of attenuation in selected portions (e.g., portion 1805) of the mask, cross-linked regions of defined thickness may be created in the photoresist. In preferred embodiments, such a mask may eliminate at least one step in the process described above for forming micro-structures, because a light source may be operated at a constant power level, with the mask itself providing a mechanism for differential light exposure in various portions of the resist.

Such a mask 1800 may be used for production-line manufacturing of micro-structures when, for example, the details of light dose have been calculated or determined by experimentation. In such a case, the mask 1800 may have patterned portions that substantially provide the requisite amount of light blocking, or attenuation, to effect molecular crosslinking to varying degrees in the photoresist layer, while operating a light source at a constant level. In some cases, so-called “gray scale” masks can be used. Filters or other methods known to those skilled in the art can also be used.

In one general aspect, a micro-structure may be fabricated so as to completely package another micro-device, such as a MEMS device. In one aspect, such packaging can afford a selectable level of hermiticity for the enclosed micro-device. One embodiment of a method to package micro-devices according to the techniques provided herein is to use a mask that will create a plurality of holes in the lid during the lid-forming process.

In one embodiment of a method for producing a hermetically-sealed MEMS package, an outline or border can be fabricated around a MEMS device using an appropriate first mask that allows light to impinge on a negative photoresist in a desired pattern (e.g., a square pattern). The first mask can be removed and a different mask can be put in its place that will ultimately form the lid. The lid mask can include a pattern that will result in the lid having a plurality of holes. The package can then be exposed to developer, which can permeate the holes, and dissolve the un-exposed (i.e., non-crosslinked) photoresist beneath the lid surface.

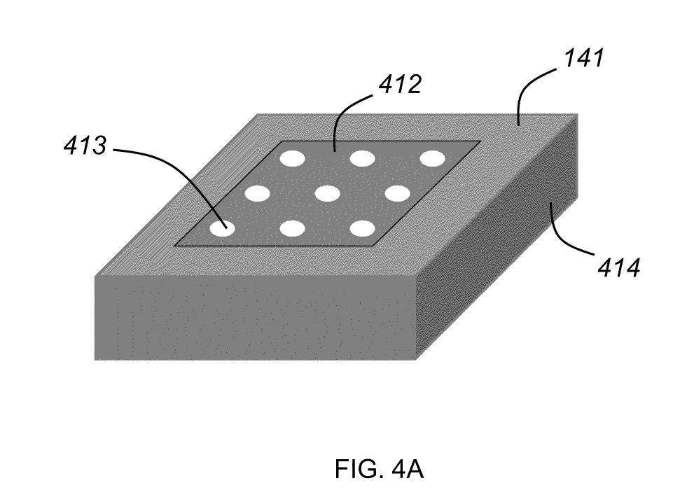

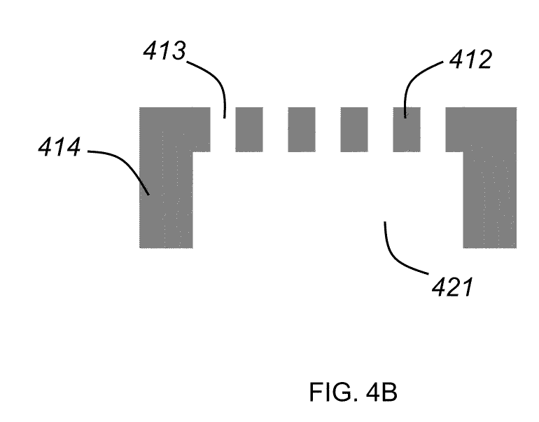

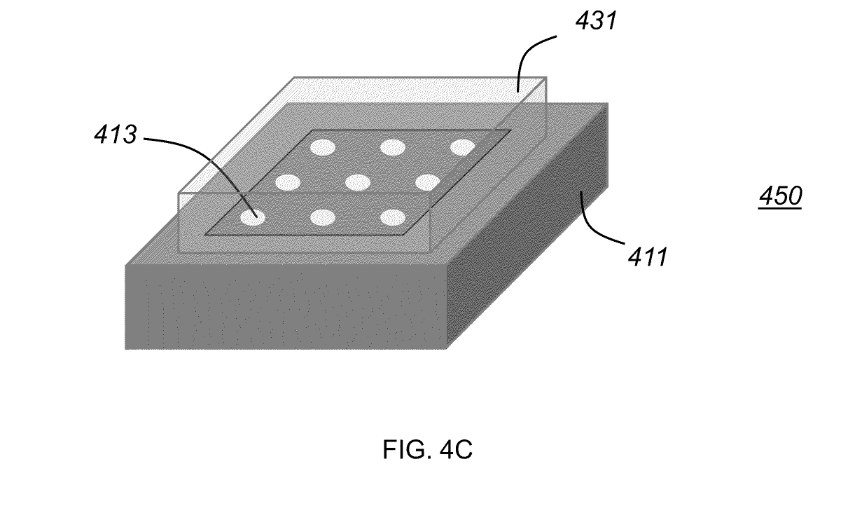

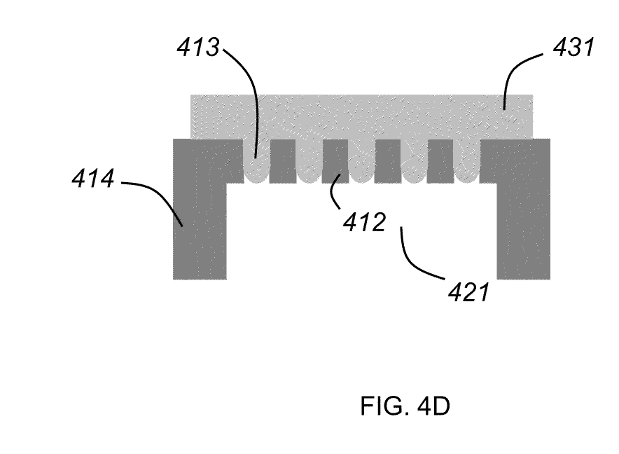

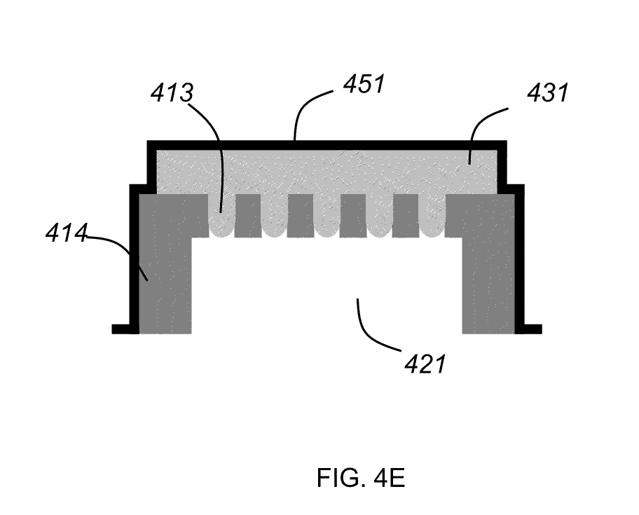

FIGS. 4A-E illustrate steps for fabricating a hermetically-sealed MEMS package, according to one embodiment. FIG. 4A is an illustration of the non-hermetic package 400 at an early stage of processing. Layer 411 is a negative photosensitive polymer or photoresist. A border 414 of the package 400 can be created by exposing the region to an appropriate dose of light to cross-link, and therefore harden the photoresist in the desired pattern. The vertical walls of the border 414 are created to support the lid 412. As described herein, a region that receives a dose of radiation higher than the interface gel dose and lower than the required dose to fully cross link the polymer results in substantially only the superficial layer being hardened. Lid 412 is realized using this method. Layer 411 therefore contains two structures: the lid 412 and the border 414 supporting the lid. While patterning the lid 412, holes 413 are also patterned. In some cases, dark circles on the mask will result in a one ore more non-cross-linked areas that will be dissolved to form holes. The holes can be created by allowing the solvent to dissolve the resist underneath the lid. In some cases, no further etching steps are required.

Generally, the holes 413 can allow developer to permeate the lid 412 to fully dissolve the unexposed polymer photoresist. The border sidewalls 414 and etch holes 413 can have any desired shape and size. The thickness of the non-hermetic package 400 is, in most cases, equal to the original thickness of the deposited polymer 411. The thickness of the lid 412 can depend on the exposure dose used to pattern the lid 412 and the holes 413.

FIG. 4B shows a cross section of the non-hermetic package 400. The underexposure of the lid 412 can result in a recess 421 that can be selectively sized to allow room for a MEMS device to occupy the recess 421.

FIG. 4C shows a sealed package 450 after depositing a second polymer layer 431. The second polymer layer 431 can have any thickness and shape and can substantially seal the holes 413 produced in earlier steps. FIG. 4D shows a cross section of the sealed package 450. In some cases, it can be possible to prevent the second polymer layer 431 from leaking through the etch holes 413 by choosing a polymer photoresist of substantially high viscosity (such as a photoresist from the SU-8 family of photoresists) and selecting appropriately-sized holes. FIG. 4D illustrates that the layer 431 has not leaked into cavity 421.

FIG. 4E shows a cross section of the final hermetic package 450. Hermeticity can be further increased by, for example, depositing a metal layer 451 over the sealed package. The metal layer 451 can be deposited using micro-fabrication techniques that will be known to those skilled in the art, such as sputtering. In some cases, metal electroplating can be performed to increase the thickness of the metal layer. Metal layer 451 can be any type of material that provides or increases the hermiticity of the package wherein only the photoresist polymer is used, e.g., package 450 as shown in FIG. 4D. Exemplary materials that can be used for this purpose include titanium, chromium, gold, and aluminum, among others.

In general, it can be advantageous to prepare the substrate onto which the photoresist will be deposited for optimal photoresist adhesion. In some cases, the method of substrate preparation should take into account the substrate itself, e.g., the substrate material, and the MEMS or other micro-device on the substrate, if present. For example, if metal is present on the substrate, Piranha (H₂SO₄:H₂O₂) etch should not be used, but an oxygen reactive ion etch may be suitable.

In general, the substrate should be completely dry and hydrophobic, depending on the type of photoresist used to create the micro-structure. In some cases, it can be advantageous to heat the substrate to a temperature that will evaporate any liquids present. In some cases, heating a substrate to 200° C. can substantially remove any water or atmospheric moisture that may be present. This heating step may not be advisable, however, if it might damage an integrated MEMS device, for example. As an alternative, deposition of a hexamethyldisilizane (HMDS) in an oven may be a suitable approach. As yet another alternative, an adhesion promoter such as NAAPS AP 150 Silicon Resources, Inc., Chandler, Ariz., USA can be used at room temperature.

### EXAMPLES

The following examples are provided to illustrate various approaches to forming a micro-structure according to the methods described herein, and is not meant to be limiting in any respect.

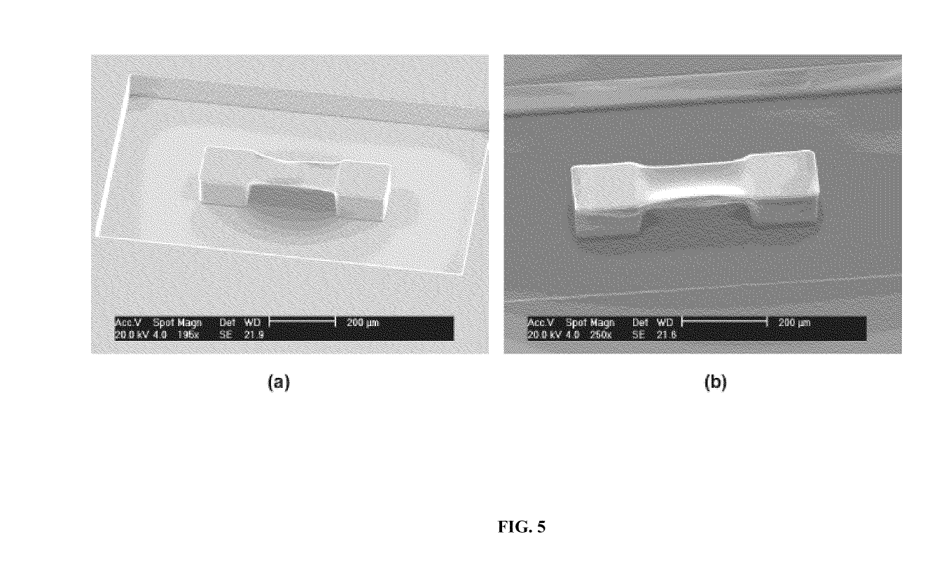

A bridge structure similar to that shown in FIG. 3C was built using two different masks as described herein. In this example, mask 1 was used to pattern the posts (e.g., posts 315a-b in FIG. 3) and mask 2 to pattern the beam (e.g., beam 335 in FIG. 3). FIGS. 5A-B are scanning electron microscope (SEM) images of the constructed bridge. The image shown in FIG. 5A shows a bridge formed using an exposure dose of 52 mJ/cm² and the image shown in FIG. 5B shows a bridge formed using an exposure dose of 67.6 mJ/cm². The bridge in FIG. 5B is thicker due to the higher exposure value.

FIG. 6 is an illustration that shows a dip in the bridge correlating to the SEM images of FIGS. 5A-B. Without wishing to be bound by theory, this effect may be due to partial development of the photoresist on the top surface of the beam and a shrinkage effect of the photoresist due to stress.

The beam retained the same thickness even after immersion in SU-8 developer for a period longer than the required development time. A second flood exposure and bake of the structure was conducted after development to further cross-link the beam.

The thicknesses of several micro-beam structures were measured by scanning electron microscopy. FIG. 7 is a chart showing the thickness of SU-8 2075 beams versus the exposure dose for several trials. SU-8 developer appears to be effective at removing the non-exposed photoresist under the beam; the bridge geometry provides easy access for the developer to reach the underlying area. For an enclosed package, however, holes should be patterned in the lid, as described herein, to allow the solvent to dissolve the photoresist under the lid.

The micro-structure shown in FIG. 7 was constructed according to the following procedure, which generally coincides with the illustrated steps of FIGS. 8A-G. A silicon wafer 805 was first cleaned using acetone and isopropyl alcohol (IPA) and subsequently rinsed with deionized (DI) water. The wafer 805 was heated to 100° C. for 10 minutes followed by application of NAAPS AP 150 at room temperature using a spinner (Brewer Science (Cee™) 100CB Photo resist Spinner/Hot plate) (FIG. 8A). A layer of SU-8 (810) was deposited at a spread speed of 500 rpm for 10 seconds and a spin speed of 2000 rpm for 30 seconds (FIG. 8B).

The SU-8 deposition parameters resulted in a film thickness of approximately 107 μm. Next, a soft bake was conducted according to the temperature parameters set out in the graph of FIG. 9. The soft bake was carried without any abrupt changes in temperature to reduce film stress and prevent potential cracking and peeling of the SU-8 photoresist in later steps. For a film thickness of approximately 107 μm, an exposure energy between 240 and 260 mJ/cm² was used. The contours of the micro-structure 817 were patterned with an exposure energy of 300 mJ/cm².

A lid 815 with etch holes 820 was patterned using a mask and an exposure energy of 57.2 mJ/cm² (FIG. 8C). At this point, a post-exposure baking (PEB) step was performed on a hot plate to selectively cross-link the exposed portion of the film. The PEB step temperature substantially followed the same profile as in the soft bake procedure (i.e., FIG. 9) with the exception of a bake period of 10 minutes at the 95° C. level. SU-8 developer was applied for 20 minutes, after which the wafer was rinsed using DI water and IPA, and then dried using nitrogen.

The patterned structure was further exposed to a 150 mJ/cm² dose of radiation, and baked at 100° C. (FIG. 8D). To seal the holes in the lid, a second, 200 μm-thick layer of SU-8 (830) was deposited (FIG. 8E). The film thickness was selected to be 200 μm to completely cover the top surface of the package. After the spreading of the second photoresist layer 830, the film had wrinkles due to the non-planar surface of the wafer. About 1-2 minutes after the soft bake started, however, the photoresist was re-flowed to achieve a smooth surface. The same soft bake procedure was carried out as shown in FIG. 9, with the exception that the bake at the 95° C. level was performed for 15 minutes. After the exposure, the PEB, and the development steps, the wafer was rinsed with deionized water and IPA and dried with nitrogen (FIG. 8F). To achieve hermiticity in the package, a 50 nm layer of titanium and a 250 nm layer of copper (together labeled as 840) were sputtered on the package (FIG. 8G).

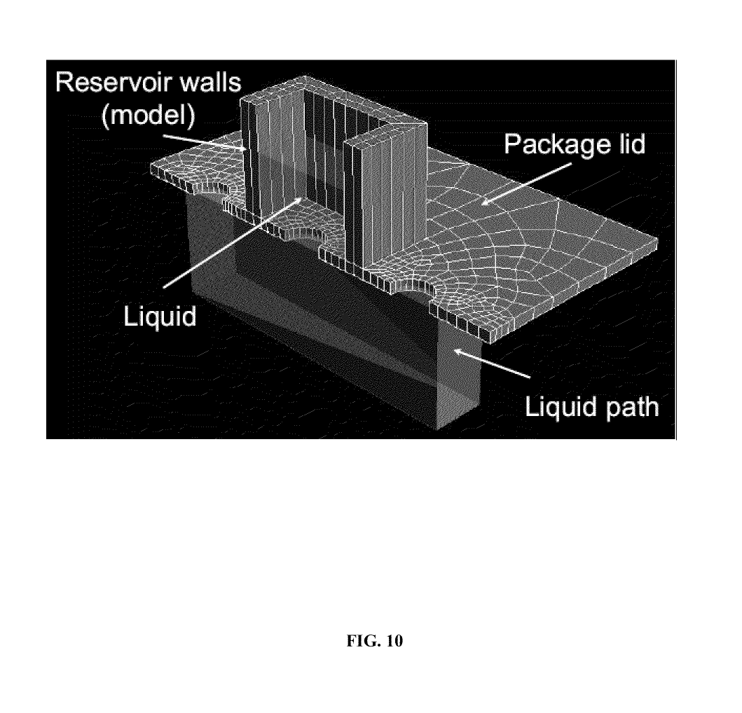

A commercial simulation software package (Coventorware microfluidics, Cary, N.C., USA) was used to ascertain whether SU-8 developer could penetrate through holes created by a mask (e.g., the mask used to create the structure shown in FIG. 8D) while blocking SU-8 photoresist. FIG. 10 shows the model that was simulated. To reduce computation time the axisymmetric option in the software package was used. The lid corresponded to the top surface of the package with one hole 40 μm in diameter. The reservoir walls were used in the model to contain the liquid (SU-8 developer and SU-8 photoresist).

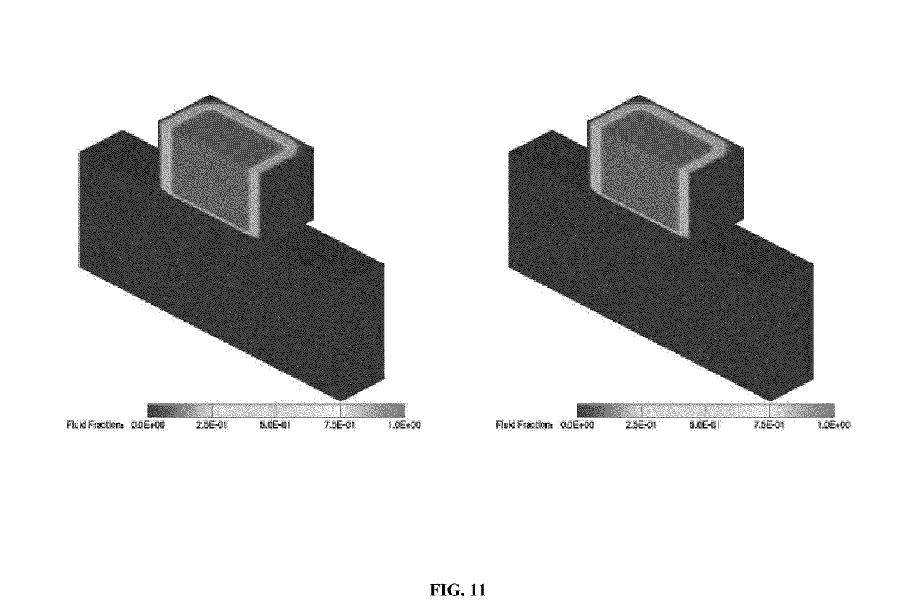

FIG. 11 shows the model results for the SU-8 developer that indicate the developer can flow through the etch hole. FIG. 11A shows the initial state of the model, where developer is present on the lid surface, and FIG. 11B shows the model after 10 seconds.

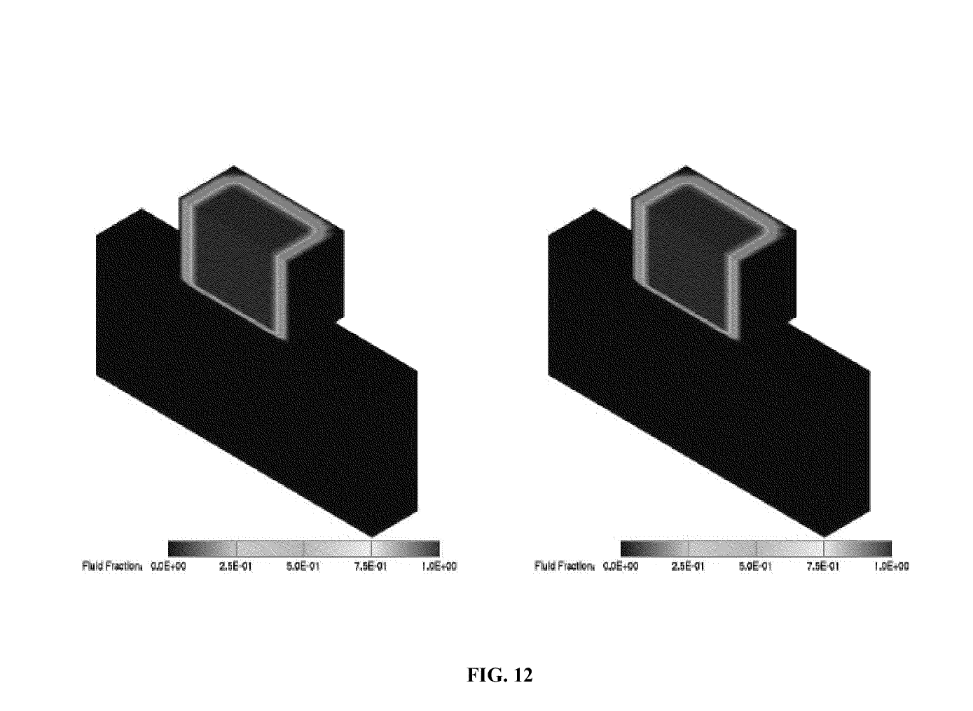

FIG. 12 shows model results where a second coat of SU-8 photoresist was applied to the lid surface. The results indicate that the photoresist does not permeate the hole(s). Without wishing to be bound by theory, it is believed that the high viscosity (22,000 cSt) of the SU-8 photoresist is at least partially responsible for the lack of flow through the holes.

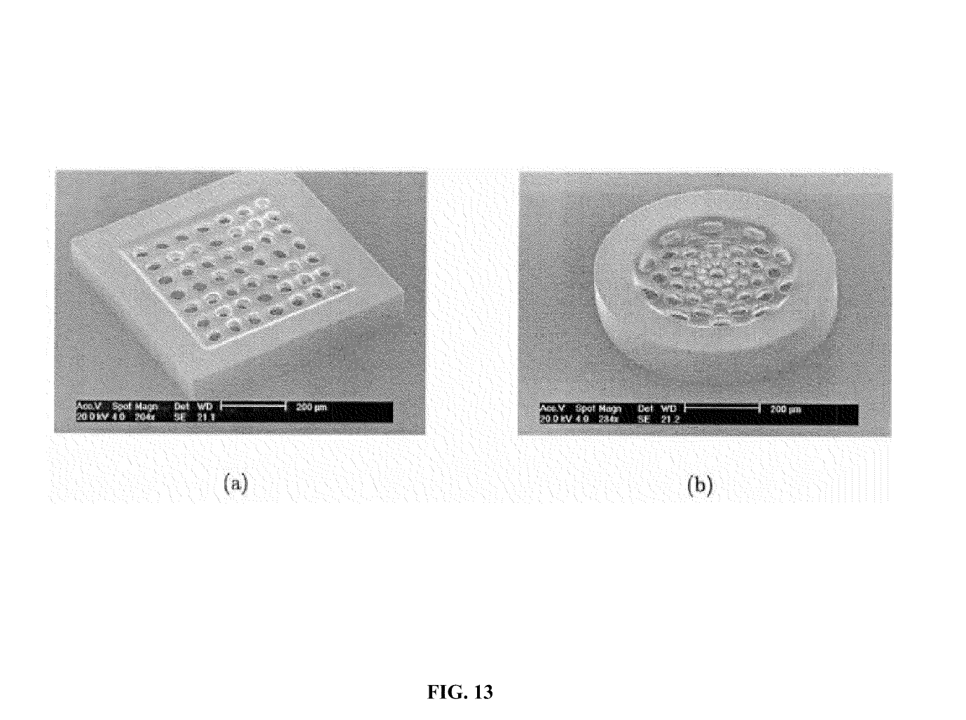

FIGS. 13A-B are SEM images of packages with different contours and etch hole patterns. FIG. 13A is an SEM image of a micro-structure having a square contour with round etch holes. FIG. 13B is an SEM image of a micro-structure having a circular contour with radial slits. In each case, the SU-8 developer completely dissolved the photoresist underneath the associated lid.

FIGS. 14A-B are SEM images of a micro-structure that can be used to package another micro-structure, such as a MEMS device, with etch holes that are 20 μm in diameter. FIG. 14B shows a close-up of the holes on the lid of the micro-structure.

FIGS. 15A-B are SEM images that shows the micro-structure packages of FIGS. 13A-B respectively after covering (i.e., sealing) the holes with a SU-8 photoresist. The top layers of the micro-structures are substantially flat, presumably due to the photoresist reflow during the soft bake step. As predicted by the models, the SU-8 applied to the lids of the micro-structures of FIGS. 13A-B did not penetrate the holes, presumably due to the high viscosity of SU-8 2075.

FIG. 16A is an SEM image of the round micro-structure of FIG. 13B oriented up-side down, where it is apparent that no photoresist leaked through the holes. FIG. 16B is an SEM image of the print of the package after it was manually removed using a pair of tweezers. No photoresist was present on the substrate which further substantiates that photoresist did not drip through the patterned etch holes.

To achieve hermiticity, a metal layer can be added to a micro-structure. FIG. 17 is an SEM image that shows a micro-structure that includes a layer of titanium and copper (FIG. 17A). FIG. 17B is an SEM image that shows further copper plating can be conducted to improve the hermiticity.

A number of embodiments have been described. Nevertheless, it will be understood that various modifications may be made without departing from the spirit and scope of this disclosure. Accordingly, other embodiments are within the scope of the following claims.

What is claimed is:

1. A method for fabricating a micro-structure, comprising:
hardening one or more areas of a photoresist layer to provide one or more support structures;
at least partially hardening a selected thickness of the photoresist layer in proximity to the one or more support structures to produce at least one structural member that couples with at least one of the support structures; and
dissolving non-hardened photoresist to produce the micro-structure.

2. The method of claim 1, wherein the hardening comprises exposing the photoresist to electromagnetic radiation having an energy substantially corresponding to the energy necessary to initiate a molecular cross-linking reaction within the photoresist.

3. The method of claim 1, wherein the photoresist is a polymer.

4. The method of claim 3, wherein the photoresist is a photoresist from the SU-8 2000 family of photoresists.

5. The method of claim 4, wherein the photoresist is SU-8 2075.

6. The method of claim 1, wherein the support structure is a post, wall, or multi-wall micro-sized support structure.

7. The method of claim 1, wherein the at least partially hardening a selected thickness of the photoresist layer in proximity to the one or more support structures to produce at least one structural member comprises exposing the photoresist layer to a radiation dose greater than a dose required to initiate cross-linking of the photoresist but less than the dose required to fully cross-link a total thickness of the photoresist.

8. The method of claim 1, wherein the dissolving non-hardened photoresist comprises exposing the micro-structural element to photoresist developer.

9. The method of claim 1, wherein the structural member comprises one or more holes or slots configured to allow a solution to penetrate the selected thickness of the photoresist layer.

10. The method of claim 9, wherein the holes or slots are sized to preferentially allow the solution to penetrate the selected thickness, while restricting non-hardened photoresist from penetrating the selected thickness.

11. The method of claim 1, wherein the micro-structure is formed around a micro-device.

12. The method of claim 11, wherein the micro-device is a microelectromechanical system or a microfluidic system.

13. The method of claim 11, wherein the micro-structure is configured to provide a variable level of hermiticity to the micro-device.

14. The method of claim 11, wherein the micro-structure is configured to allow a component of the micro-device to extend through the micro-structure, such that a desired level of hermiticity is provided to the micro-device while allowing the micro-device to be interfaced with other devices exterior to the micro-structure.

15. The method of claim 1, wherein the micro-structure is formed from one species of photoresist.

16. A method for packaging a MEMS device, comprising:
forming a hardened border section of a photoresist layer in proximity to a MEMS device by exposing the border section to a dose of radiation to crosslink the photoresist in the border section using a first lithographic mask;
replacing the first lithographic mask with a second lithographic mask and exposing the photoresist layer with a dose of radiation to partially crosslink a superficial portion of the photoresist layer, wherein the second lithographic mask is configured to produce a plurality of holes in the superficial portion of the photoresist layer; and
dissolving remaining non-crosslinked photoresist using a developer solution, thereby creating a chamber that encloses the MEMS device.

17. The method of claim 16, further comprising applying a top-layer of photoresist to seal the plurality of holes.

18. The method of claim 16, further comprising applying a metal layer upon the top-layer of photoresist.

19. The method of claim 18, wherein the applying a metal layer comprises one or more of physical vapor deposition and chemical vapor deposition.

20. The method of claim 19, wherein the applying a metal layer comprises sputtering one or more of titanium, chromium, gold, or aluminum.

21. An article of manufacture, comprising one or more micro-structural supports formed from hardened photoresist and configured to support a micro-structural element composed of the photoresist that spans the one or more micro-structural supports, wherein the article of manufacture is configured to encapsulate a MEMS device, thereby providing a variable level of hermiticity.

22. A method of forming a micro-structure for encapsulating a micro-device, comprising:
cross-linking, to variable extents, select thicknesses and areas of a photoresist layer using a lithographic mask, the lithographic mask being configured to produce patterns of variably-attenuated electromagnetic radiation, wherein the patterns define various structural elements of the micro-structure by virtue of the cross-linked thicknesses and areas; and
dissolving non-crosslinked photoresist, thereby forming a cavity suitable for encapsulating the micro-device.

23. The method of claim 22, wherein the micro-device is a MEMS device.
